(19) United States
(12) Patent Application Publication
(10) Pub. No.: US 2016/0020086 A1
(43) Pub. Date: Jan. 21, 2016

(54) DOPING CONTROL METHODS AND RELATED SYSTEMS

(71) Applicant: TAIWAN SEMICONDUCTOR MANUFACTURING COMPANY, LTD., Hsin-Chu (TW)

(72) Inventors: Chun Hsiung Tsai, Xinpu Township (TW); Ming-Te Chen, Hsinchu City (TW)

(21) Appl. No.: 14/335,257

(22) Filed: Jul. 18, 2014

(51) Int. Cl. H01L 21/02; H01L 21/67; H01L 21/687; C30B 25/08; C30B 25/14

(52) U.S. Cl. CPC H01L 21/02068; C30B 25/08; C30B 25/14; H01L 21/68742; H01L 21/67069; H01L 21/0257

(57) ABSTRACT

A system for cleaning dopant contamination in a process chamber is disclosed. The system includes a susceptor and a chamber kit component, a first plurality of lamps configured to heat the susceptor, a second plurality of lamps configured to heat the chamber kit component, and a gas supply configured to provide a chlorine cleaning gas. The system is configured to deposit a layer on a substrate at a deposition temperature and perform an in-situ clean of the process chamber, including the chamber kit component, at the deposition temperature. A method for cleaning dopant contamination includes depositing a layer over a substrate at a deposition temperature, performing an in-situ clean of the process chamber and a process kit component at the deposition temperature, unloading the substrate, and performing a dedicated clean at a clean temperature. In some examples, the clean temperature is about equal to the deposition temperature.

### BACKGROUND

The electronics industry has experienced an ever increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As merely one example, semiconductor layers may be deposited and/or formed on a substrate by one or more of a variety of processes such as chemical vapor deposition (CVD), physical vapor deposition (PVD), atomic layer deposition (ALD), thermal oxidation, electron-beam (e-beam) evaporation, epitaxial growth techniques including vapor-phase epitaxy (VPE), metalorganic CVD (MOCVD), and molecular-beam epitaxy (MBE), as well as other suitable deposition techniques. It is sometimes desirable, during layer growth and/or deposition, to dope the layer by addition of impurities during the growth process. In one instance, introduction of an impurity gas during an epitaxial growth process can provide for in-situ doping of an epitaxially grown layer. However, such doping processes can lead to process chamber contamination (e.g., chamber walls and other chamber surfaces), and may include contamination of chamber process kits (e.g., including a susceptor, a dome, a base ring, an upper liner, and a lower liner). In one example, subsequent processing in a contaminated process chamber can result in unintentional layer doping (i.e., autodoping), for example by chamber and/or chamber kit outgassing, that can lead to variations in doping, resistance, and threshold voltage. Existing chamber cleaning techniques employ a dedicated, high-temperature cleaning process after deposition and/or growth of each layer, which may result in pits and/or other defects in the process chamber or chamber kit, while also insufficiently cleaning the process chamber. Thus, existing chamber cleaning techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-section of a CVD system in accordance with some embodiments;

FIG. 2 is a schematic diagram illustrating various autodoping mechanisms;

FIG. 3 is a flow chart illustrating an embodiment of a method of cleaning a chamber kit and/or other interior portions of a system in accordance with some embodiments;

FIG. 4 is a flow chart illustrating an embodiment of a method of cleaning a chamber kit and/or other interior portions of a system in accordance with other embodiments; and

FIG. 5 is a schematic cross-section of a CVD system in accordance with other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

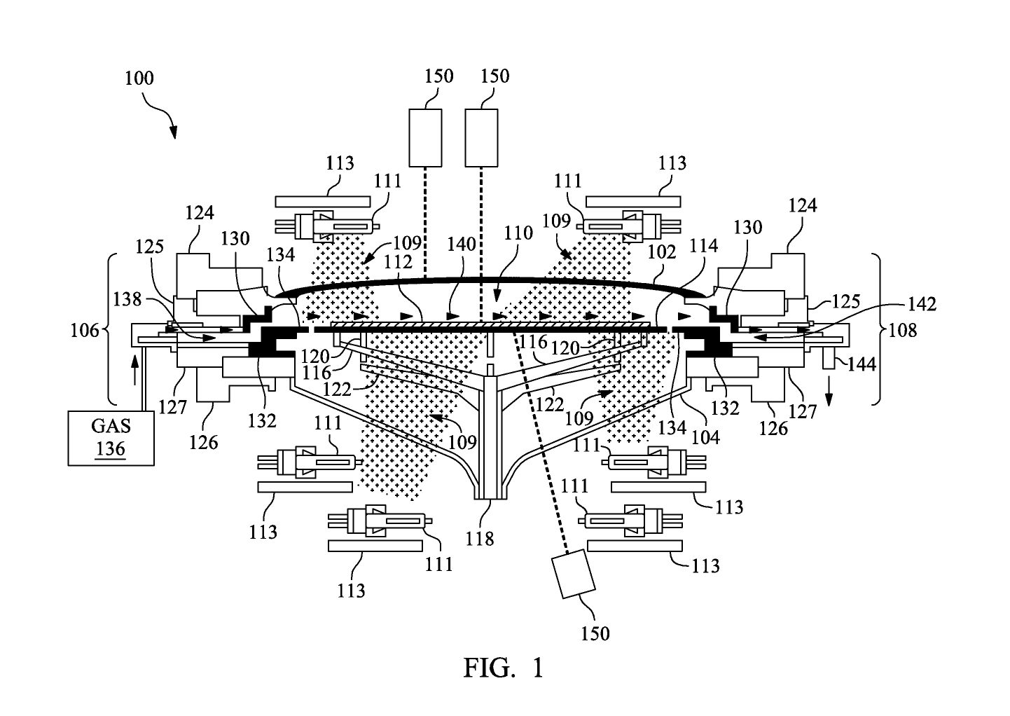

FIG. 1 illustrates a schematic cross-section of a chemical vapor deposition (CVD) epitaxy system 100 (hereinafter referred to as the system 100) in accordance with some embodiments. While the embodiments shown and described herein are discussed primarily with regard to CVD epitaxy systems (such as the system 100), it is noted that the system (e.g., the system 100) may accommodate different types of processes, for example depending on selected process parameters such as pressure, deposition temperature, deposition time, source gas, and/or other parameters as known in the art. Furthermore, those skilled in the art having the benefit of the present disclosure will understand that the advantages of the methods and systems described herein may be advantageously applied to a variety of semiconductor systems and processes. Returning to FIG. 1, the illustrated system 100 includes an upper dome 102, a lower dome 104, and side wall regions 106, 108 which together define a process chamber 110. The upper dome 102 and lower dome 104 may be made from a material such as quartz, which is transparent to radiation (schematically illustrated by rays 109) emitted from lamps 111 that are mounted outside the process chamber 110 and which are used to heat the process chamber 110, and in particular the susceptor 114 (as well as any loaded substrate 112). In some embodiments, reflectors 113 (i.e., mirrors) may be coupled to the lamps 111 in order to redirect lamp radiation toward the susceptor 114. In some examples, induction heating (e.g., via radio frequency coils) may be used in conjunction with, or instead of, the lamps 111. In the illustrated embodiment of the system 100, although shown as individual lamps, each of the lamps 111 may represent a plurality of lamps 111. In some examples, a top set of lamps of the plurality of lamps 111 may include around 30-35 lamps, a bottom set of lamps of the plurality of lamps 111 may include around 40-45 lamps, and a total number of lamps of the plurality of lamps 111 may include around 70-80 lamps. In various embodiments, one or more pyrometers 150 are used to measure the temperature of for example, the susceptor 114, the substrate 112, the upper dome 102, and/or other components of the system 100. In some embodiments, the one or more pyrometers 150 include radiation pyrometers, spectral pyrometers, narrow-band pyrometers, and/or broadband pyrometers. Also, in some embodiments, a power setting of the lamps 111, and thus the temperature of the system 100, is controlled by temperature measurements of the pyrometers 150. In some embodiments, the pyrometers 150 may be calibrated by means of one or more thermocouples attached to for example, the susceptor 114, the upper dome 102, and/or other components of the system 100.

In some embodiments, a single substrate such as the substrate 112, is loaded into the process chamber 110. In other embodiments, multiple substrates may be loaded into the process chamber 110. In the illustrated embodiment, substrate 112 is mounted onto a susceptor 114 that may be rotated by support arms 116 connected to a drive shaft 118. In various embodiments, rotation ensures good uniformity of a deposited layer. A plurality of elevator pins 120 can be coupled to the susceptor 114 in a manner which provides for vertical movement of the elevator pins 120, for example through openings within the susceptor 114. As such, the elevator pins 120 may be moved up or down by one or more lift arms 122, thereby providing for vertical displacement of the susceptor 114 (as well as any loaded substrate 112).

Side wall regions 106, 108 may further include an upper clamp ring 124, a lower clamp ring 126, an upper base ring 125, a lower base ring 127, an upper liner 130, a lower liner 132, and a pre-heat ring 134. The upper clamp ring 124 and the lower clamp ring 126 can be used to secure the upper dome 102 and the lower dome 104 to each of the upper base ring 125 and the lower base ring 127, respectively. In various embodiments, one or more O-rings may be disposed at an interface between the upper clamp ring 124 and the upper base ring 125, as well as at an interface between the lower clamp ring 126 and the lower base ring 127, enabling a pressure seal of the process chamber 110. Such O-rings may additionally provide structural support and help to reduce thermal stress.

As shown in FIG. 1, the system 100 also includes a gas supply 136. By way of example, the gas supply 136 may include a carrier gas, a precursor gas, a dopant gas, and/or a cleaning gas. In some embodiments, the carrier gas may include an inert gas such as nitrogen, helium, argon, or hydrogen. In some embodiments, the precursor gas may include silane, disilane, trisilane, mono-methyl silane, dichlorosilane, trichlorosilane, silicon tetrachloride, boron trichloride, diboron tetrachloride, germanium tetrachloride, germanium chloroform, germanium tetrafluoride, germanium bromide, or germanium iodide. In some embodiments, the dopant gas may include phosphine (PH₃), diborane, antimony, arsenic, boron, carbon, germanium, tin, gallium, indium, or phosphorus. In some embodiments, the cleaning gas may include hydrogen chloride (HCl) gas or chlorine (Cl₂) gas.

One or more of the carrier gas, the precursor gas, the dopant gas, and/or the cleaning gas is supplied to the process chamber 110 by way of a gas supply line 137 and inlet port of the system 100. The supplied gas flows through a passage 138 of the side wall region 106, across the pre-heat ring 134, and across the susceptor 114 (as well as any loaded substrate 112), in a direction indicated by arrows 140. In various embodiments, the gas is then evacuated from the process chamber 110 through a passage 142 of the side wall region 108, exiting through an evacuation port 144 that may be used for exhausting gases and/or by-products from the process chamber 110. As described above and illustrated in FIG. 1, the substrate 112 can be loaded on a substantially horizontally oriented susceptor 114 and the supplied gas may flow parallel to the substrate 112. However, in other embodiments, the supplied gas may flow perpendicular to the susceptor 114 (as well as any loaded substrate 112), for example as in the case of a pancake reactor (or disk reactor). In yet other embodiments, one or more substrates 112 may be loaded in a substantially vertical orientation (e.g., as in a barrel reactor), with the supplied gas flowing parallel to the substrate 112.

The process chamber 110, including chamber kit components, may be subject to contamination (e.g., dopant contamination) during processing (e.g., deposition sequences) and require periodic cleaning to reduce such contamination which could otherwise also contaminate substrates 112 which are subsequently processed within a contaminated system 100. As used and described herein, the terms “process kit”, “chamber kit”, or “chamber process kit” may be used interchangeably to describe one or more of the susceptor 114, the upper dome 102, the lower dome 104, the upper base ring 125, the lower base ring 127, the upper clamp ring 124, the lower clamp ring 126, the upper liner 130, the lower liner 132, the pre-heat ring 134, as well as other inserts, shields, assemblies, valves, traps, O-rings, and/or other components of the system 100. In some examples, a cleaning process may be performed after each deposition cycle or after a deposition sequence including a plurality of cycles. Conventionally, after removal of any previously loaded substrate (e.g., the substrate 112), a dedicated cleaning process is performed at a high-temperature (e.g., at about 1200-1250° C.) by introducing a hydrogen chloride (HCl) cleaning gas into the process chamber 110 to clean the chamber kit and/or other interior portions of the system 100. In some examples, the cleaning process may be performed using a mixture of HCl and hydrogen (H₂). Such cleans may be used to effectively break-down contamination deposits within the system 100, converting them into volatile by-products that can be exhausted from the system 100 by way of the evacuation port 144.

One concern with conventional high-temperature HCl-based cleans, as described above, is that they over actively clean and etch the susceptor 114 or other chamber kit components, which may result in pit formation in one or more components of the system 100. In addition, the lamps 111 used to heat the system 100 may not sufficiently heat all system 100 components to the desired cleaning temperature (e.g., greater than about 1200° C.). For example, the chamber kit components may not reach the desired cleaning temperature because such components are not in the direct path of the radiation (schematically illustrated by rays 109) emitted from the lamps 111. For HCl-based cleaning processes, a temperature of greater than about 620° C. is needed in order for HCl to effectively clean (i.e., etch) contaminated surfaces of the system 100. At cleaning temperatures lower than about 620° C. for HCl-based cleaning processes, contamination (e.g., dopant contamination) introduced during a prior epitaxial growth process may not be remove but instead may remain on surfaces of contaminated system 100 components.

Considering the system 100 of FIG. 1, the upper dome 102 and the lower dome 104, which comprise a material such as quartz, may be substantially transparent to radiation emitted from the lamps 111 and may thus only reach temperatures of approximately 400-500° C. Similarly, one or more parts of the side wall regions 106, 108, including chamber kit components such as the upper base ring 125, the lower base ring 127, the upper clamp ring 124, the lower clamp ring 126, the upper liner 130, and the lower liner 132, may only reach temperatures of approximately 100-250° C. Thus, the cleaning effectiveness of HCl on the upper and lower domes 102, 104 and the chamber kit components listed above may be greatly diminished, and contamination (e.g., dopant contamination) deposited during a prior epitaxial growth process may not be effectively removed. In addition, in some examples, the upper and/or lower clamp rings 124, 126 may not be directly exposed to the cleaning reactants (e.g., HCl), which also can detrimentally impact the effectiveness of HCl-based cleaning. As a direct consequence of ineffectively cleaned system 100 components, outgassing of contaminated system 100 components may occur during subsequent epitaxial growth processes. Such outgassing may result in autodoping of the substrate 112, and may include unintentional doping of an epitaxially grown layer on the substrate 112. In some examples, autodoping may lead to variations in doping, resistance, and/or threshold voltage of devices fabricated within an autodoped substrate 112. It should be noted that while dopants intentionally introduced via an impurity gas during an epitaxial growth process can be introduced in a controlled manner (e.g., by way of a process recipe), dopants unintentionally introduced via autodoping are introduced in an uncontrolled manner. Thus, embodiments of the present disclosure present methods and systems which provide effective cleaning of the process chamber (e.g., process chamber 110) and chamber kit of the system 100, while mitigating both autodoping and damage to system 100 components.

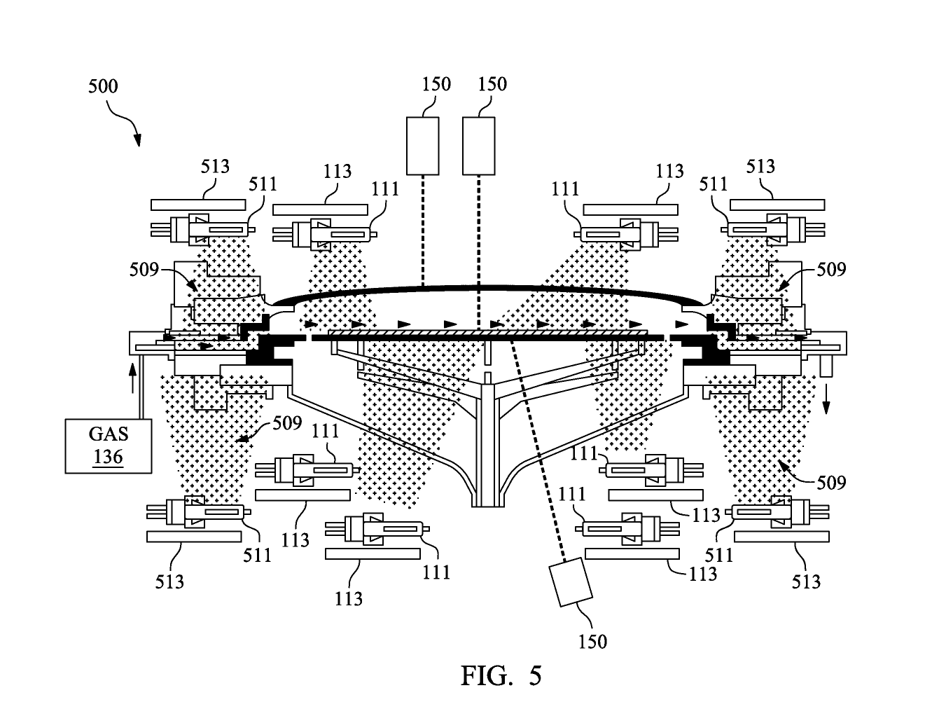

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and systems for solving the autodoping issues discussed above. In some embodiments, conventional high-temperature (e.g., greater than about 1200° C.), HCl-based cleans are replaced with Cl₂-based cleans, which can effectively clean the system 100 at temperatures below about 700° C. In some embodiments, a Cl₂-based clean can be effectively performed at temperatures as low as about 500° C. In some embodiments, a Cl₂-based clean includes a nitrogen (N₂) and/or helium (He) carrier gas. Additionally, in some embodiments, a Cl₂-based clean may be performed at temperatures which are substantially equal to a deposition temperature (e.g., an epitaxial deposition temperature), thus eliminating temperature ramp-up/ramp-down times, reducing thermal cycles, and extending the lifetime of the susceptor 114 (e.g., from about 3000 wafer runs to about 6000 wafer runs). In some embodiments, in-situ cleans may be integrated within/between epitaxial growth process steps, mitigating dopant contamination build-up occurring during the epitaxial growth process and simplifying any subsequent, dedicated cleaning process performed after a substrate is unloaded from the system 100. In other embodiments, the system 100 further includes dedicated lamps (as shown and discussed below with reference to FIG. 5) that provide for enhanced heating of chamber kit components. In yet other embodiments, the susceptor 114 may be moved, as described above, to improve upper dome heating and exposure of one or more chamber kit components to cleaning reactants.

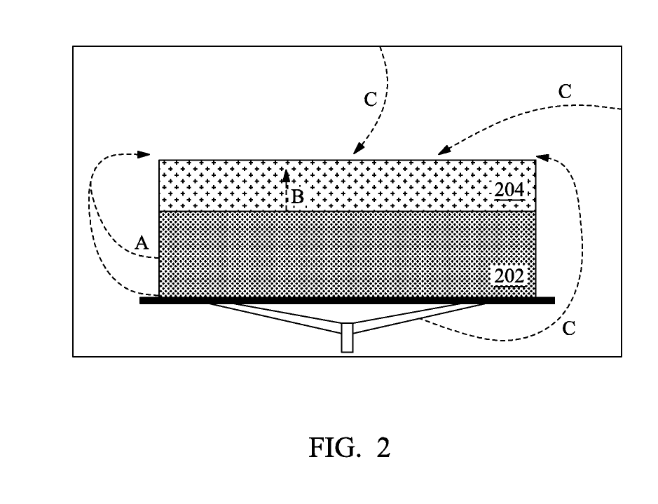

By way of example, and to provide a more complete description of autodoping as well as at least some of the issues addressed by the embodiments disclosed herein, FIG. 2 provides a schematic diagram illustrating various autodoping mechanisms that may occur during a layer growth process. For example, during epitaxial growth of a layer 204 on a substrate 202, dopants may be unintentionally introduced into the layer 204 via one or more mechanisms, labeled as A, B, and C. In a first example, an autodoping mechanism A may include gas-phase autodoping, where dopants from an edge or backside of the substrate 202 are introduced into the layer 204. In another example, an autodoping mechanism B may include solid-state out-diffusion from the substrate 202 (which may include a heavily-doped substrate having a dopant concentration greater than about 10¹⁸ cm⁻³) into the layer 204. In a third example, an autodoping mechanism C may include system autodoping, where dopants from a reactor wall, chamber kit components, or other system components are introduced into the layer 204. In addition to the uncontrolled nature of unintentional dopant introduction via autodoping, as noted above, autodoping also limits a minimum layer thickness that can be grown with controlled, intentional doping as well as a minimum dopant level of a grown layer. In some examples, mechanisms A and B occur at temperatures greater than about 1000° C. As such, the relatively lower temperatures used in the embodiments described herein (e.g, 500-700° C.) advantageously mitigate such autodoping mechanisms. Additionally, the methods and systems described herein provide for minimizing and/or eliminating the impact of autodoping mechanism C, for example through the use of Cl₂-based cleans, in-situ cleans performed within/between epitaxial growth process steps, dedicated lamps, and/or other techniques described below.

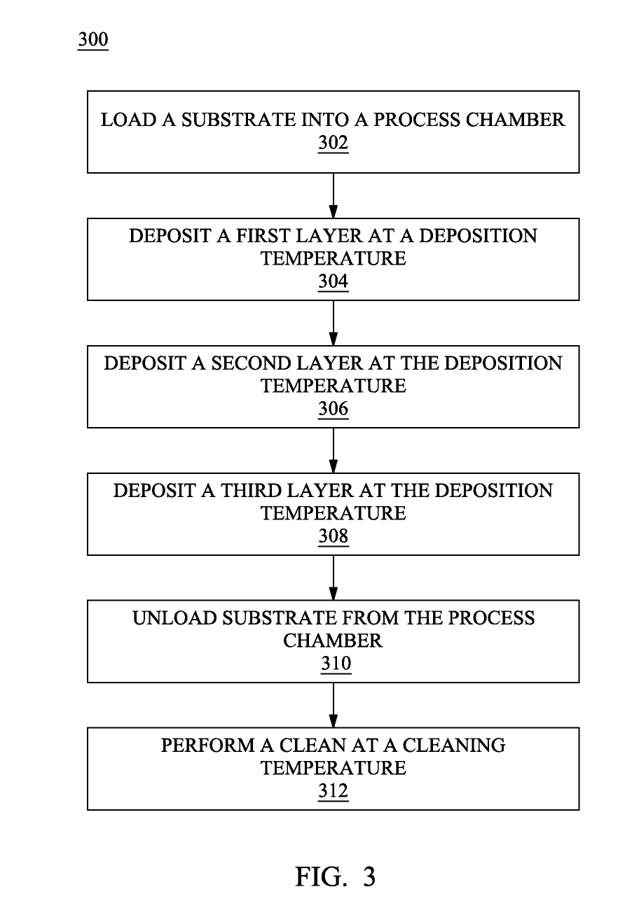

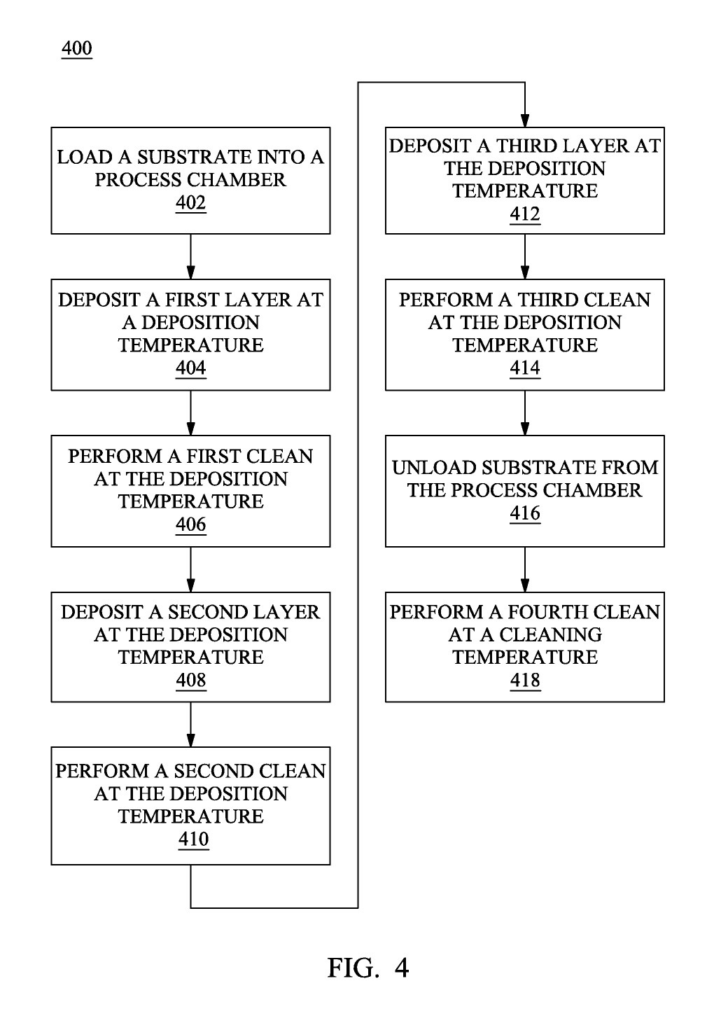

Referring now to FIG. 3, illustrated is a method 300 for cleaning a chamber kit and/or other interior portions of a CVD epitaxy system, such as the system 100 of FIG. 1. The method 300 is described below with reference to the system 100. However, it will be understood that additional steps can be provided before, after or during the method 300, and some of the operations described herein may be replaced by other operations or eliminated. Similarly, additional features may be present in the system 100 and/or features present may be replaced or eliminated in additional embodiments. The method 300 is described below with reference to a conventional high-temperature (e.g., greater than about 1200° C.), HCl-based cleaning process. Nevertheless, it will be understood that certain embodiments of the methods and systems described below (e.g., with reference to FIGS. 4 and 5) may also be implemented using a method substantially similar to the method 300.

The method 300 begins at block 302 where a substrate is loaded into a process chamber. Referring to the embodiment of FIG. 1, the substrate 112 is loaded into the process chamber 110. The substrate 112 may be processed according to a variety of different processes within the process chamber 110, for example depending on selected process parameters such as pressure, deposition temperature, deposition time, source gas, and/or other parameters as known in the art. Consider for example, that highly-doped epitaxial source/drain regions of a field-effect transistor (FET) are to be grown on the substrate 110. Highly-doped source/drain regions may be used to reduce a contact resistance of the source/drain regions, the formation of which may include the deposition of a plurality of layers having distinct doping concentrations, as described below. In one example, highly-doped (e.g., with a doping concentration greater than about 10²⁰ cm⁻³) N-type SiP source/drain regions are formed by introduction of an N-type dopant, such as phosphine (PH₃), into the process chamber 110 together with a silicon precursor such as one of the silicon precursors described above. To achieve such high doping levels, high chamber pressure and high dopant gas concentrations may be used. In some cases, N-type SiP source/drain regions may be formed at a chamber pressure of about 600 Torr and about a 10% PH₃ concentration. In other cases, N-type SiP source/drain regions may be formed at a chamber pressure of about 300 Torr and about a 100% PH₃ concentration. Such high pressures and dopant gas concentrations directly contribute to the contamination of the process chamber 110 (and chamber kit components). In a similar manner, and resulting in similar process chamber 110 contamination issues, highly-doped (e.g., with a doping concentration greater than about 10²⁰ cm⁻³) P-type SiGeB source/drain regions may be formed by introduction of a P-type dopant, such as diborane (B₂H₆), into the process chamber 110 together with silicon and germanium precursors such as dichlorosilane and germane, respectively. Other precursors and dopant gases may also be used, as described above.

The method 300 then proceeds to block 304, where a first layer is deposited at a deposition temperature. In the embodiments described herein, the deposition temperature (e.g., of a CVD epitaxial deposition process) may include temperatures in the range of between around 550° C. and around 680° C. By way of example, consider the formation of N-type SiP or P-type SiGeB source/drain regions as described above. In some cases, an embodiment of block 304 may include CVD epitaxial deposition of a first SiP layer having a first phosphorous dopant concentration of around 2×10²⁰-7×10²⁰ cm⁻³. In other cases, an embodiment of block 304 may include CVD epitaxial deposition of a first SiGeB layer having a first boron dopant concentration of around 1×10²⁰-5×10²⁰ cm⁻³. Formation of each of the N-type SiP or P-type SiGeB source/drain regions, and their respective dopant concentrations, may be controlled by appropriate selection and introduction of one or more precursor, carrier, and dopant gases (as described above) into the process chamber 110 and provided by the gas supply 136.

The method 300 then proceeds to block 306, where a second layer is deposited at the deposition temperature. Continuing with the example of formation of N-type SiP or P-type SiGeB source/drain regions, an embodiment of block 306 may include CVD epitaxial deposition of a second SiP layer having a second phosphorous dopant concentration of around 2×10²¹-3×10²¹ cm⁻³. In other cases, an embodiment of block 306 may include CVD epitaxial deposition of a second SiGeB layer having a second boron dopant concentration of around 2×10²⁰-1×10²¹ cm⁻³. The method 300 then proceeds to block 308, where a third layer is deposited at the deposition temperature. In some examples, an embodiment of block 308 may include CVD epitaxial deposition of a third SiP layer having a second phosphorous dopant concentration of around 5×10²⁰-3×10²¹ cm⁻³. In other examples, an embodiment of block 308 may include CVD epitaxial deposition of a third SiGeB layer having a third boron dopant concentration of around 2×10²⁰-1×10²¹ cm⁻³.

In each of the blocks 304, 306, 308, deposition of a doped epitaxial layer also results in dopant (e.g., phosphorous, boron, or other dopant used according to a particular process) deposition and accumulation within the process chamber 110 (e.g., on the process chamber 100 walls and other chamber surfaces), and may include contamination of the chamber process kit, as described above. Subsequent substrate 112 processing in a contaminated process chamber 110 may result in autodoping (e.g., due to outgassing), and can result in variations in doping, resistance, and threshold voltage. Prior to cleaning the process chamber 110, the method proceeds to block 310 where the substrate 112 is unloaded from the process chamber 110. The method then proceeds to block 312, where a cleaning process is performed at a cleaning temperature. In a conventional example, an embodiment of the block 312 may include a high-temperature, dedicated cleaning process performed at a cleaning temperature of about 1200-1250° C. and may employ HCl as the cleaning gas. Such high-temperature HCl-based cleans, which can result in pits and/or other defects in the process chamber 110 or chamber kit components, are also not completely effective at cleaning, for one or more of the reasons described above. For example, some chamber kit components may not be in the direct path of the radiation (schematically illustrated by rays 109) emitted from the lamps 111, and thus such components may not be sufficiently heated (e.g., to the cleaning temperature) and cleaned. In addition, conventional high-temperature HCl-based cleans necessitate temperature ramp-up and ramp-down (e.g., between the deposition and cleaning temperatures), where such thermal cycles cost valuable time and can reduce the lifetime of the susceptor 114. To be sure, embodiments of the present disclosure, for example with reference to FIGS. 4 and 5 below, may include the method 300 employed with a system 500 (FIG. 5) having dedicated chamber kit heating lamps or may be performed using Cl₂ as the cleaning gas, providing for a reduced cleaning temperature of about 500-700° C., which is substantially the same as the deposition temperature.

Referring now to FIG. 4, illustrated is a method 400 for cleaning a chamber kit and/or other interior portions of a CVD epitaxy system, such as the system 100 (FIG. 1) or the system 500 (FIG. 5). By way of example, the method 400 is described below with reference to the system 500 (FIG. 5). Specifically, referring to FIG. 5, the illustrated embodiment of the system 500 includes lamps 511 that are mounted outside the process chamber 110. In some embodiments, reflectors 513 may be coupled to the lamps 511 in order to redirect lamp radiation. In some examples, induction heating (e.g., via radio frequency coils) may be used in conjunction with, or instead of, the lamps 511. In the illustrated embodiment of the system 500, although shown as individual lamps, each of the lamps 511 may represent a plurality of lamps 511. In some examples, a top set of lamps of the plurality of lamps 511 may include around 10-20 lamps, a bottom set of lamps of the plurality of lamps 511 may include around 10-20 lamps, and a total number of lamps of the plurality of lamps 511 may include around 20-40 lamps. In some embodiments, the one or more pyrometers 150 can be used to measure the temperature of for example, the susceptor 114, the substrate 112, the upper dome 102, and/or other components of the system 100, and thereby control a power setting of the lamps 111, as discussed above, and also may be used to control a power setting of the lamps 511. In some embodiments, one or more pyrometers or thermocouples may be used to measure a temperature of one or more chamber kit components.

The lamps 511 provide a dedicated heat source (schematically illustrated by rays 509) which may be used to heat the chamber kit components such as the upper base ring 125, the lower base ring 127, the upper clamp ring 124, the lower clamp ring 126, the upper liner 130, and the lower liner 132. In some embodiments, the lamps 511 may also provide additional heating to the upper dome 102 and the lower dome 104. In the system 100 (FIG. 1), the chamber kit components may only reach temperatures of approximately 100-250° C. since such components are not in the direct path of the radiation, while the upper and lower domes 102, 104 may only reach temperatures of approximately 400-500° C. since the domes may be at least partially transparent to radiation. Thus, the chamber kit components and the upper/lower domes 102, 104 may not be effectively cleaned. In contrast, the lamps 511 of the system 500 provides an additional heat source for heating the chamber kit components, such as those listed above, and/or the upper/lower domes to temperatures greater than about 500° C., and up to about 700° C., providing for effective cleaning at the deposition temperatures (discussed above) using Cl₂ as the cleaning gas.

It will be understood that additional steps can be provided before, after or during the method 400, and some of the operations described herein may be replaced by other operations or eliminated. Similarly, additional features may be present in the system 500 and/or features present may be replaced or eliminated in additional embodiments. In accordance with embodiments of the present disclosure, the method 400 is described below with reference to a Cl₂-based clean, which may be used to effectively clean the system 500 at cleaning temperatures from about 500-700° C. (substantially equal to a deposition temperature). However, it will be understood that in some embodiments, the method 400 may also be used to implement a Cl₂-based clean for the system 100 at cleaning temperatures from about 500-700° C. Further, it will be understood that certain embodiments of the methods and systems described below (e.g., using a Cl₂-based clean or dedicated chamber kit lamps as shown in FIG. 5) may also be implemented using a method substantially similar to the method 300.

The method 400 begins at block 402 where a substrate is loaded into a process chamber. Referring to FIG. 5, the substrate 112 is loaded into the process chamber 110. Similar to the system 100, the system 500 may be used to process the substrate 112 according to a variety of different processes within the process chamber 110, for example depending on selected process parameters such as pressure, deposition temperature, deposition time, source gas, and/or other parameters as known in the art. Consider once again the deposition of a plurality of layers having distinct doping concentrations for the formation of highly-doped epitaxial source/drain regions of a FET on the substrate 112. In some embodiments, rather than sequentially depositing a plurality of layers and performing a dedicated clean after unloading the substrate 112, as discussed above with reference to the method 300, the method 400 includes embodiments where in-situ cleans are performed after deposition of each of the plurality of layers. However, it will be understood that other embodiments may include performing such in-situ cleans after deposition of at least one of the plurality of layers. As described herein, embodiments of the method 400 help to mitigate dopant contamination build-up that may occur during successive epitaxial deposition process steps and simplifies any subsequent, dedicated cleaning process of the process chamber 110, and chamber kit components.

The method 400 then proceeds to block 404, where a first layer is deposited at a deposition temperature, which includes temperatures in the range of between around 550° C. and around 680° C. An embodiment of block 404 may include CVD epitaxial deposition of a first SiP layer having a first phosphorous dopant concentration (e.g., of around 2×10²⁰-7×10²⁰ cm⁻³), deposition of a first SiGeB layer having a first boron dopant concentration (e.g., of around 1×10²⁰-5×10²⁰ cm⁻³), or deposition of another epitaxial layer as known in the art.

The method 400 then proceeds to block 406, where a first clean is performed at the deposition temperature, which may include temperatures in the range of between around 550° C. and around 680° C., as used for the first layer deposition at block 404. In the embodiments described herein, the first clean is performed in-situ. As used herein, the term “in-situ” or “in-situ clean” is used to describe a case where the substrate 112 remains loaded within the process chamber 110 during the cleaning process. In some embodiments, the in-situ first clean is performed for a time period having a duration which lasts from about 5 seconds to about 20 seconds. By way of example, after deposition of the first layer (block 404) and after the cessation of the flow of precursor and/or dopant gases used to deposit the first layer, the first clean (block 406) may be performed by flowing the cleaning gas into the process chamber 110, for example while the process chamber 110 remains at the deposition temperature. In some embodiments, the cleaning gas includes Cl₂ gas, which can effectively clean (i.e., etch) dopant contamination within the process chamber 110 at temperatures below about 700° C. In some embodiments, a carrier gas such as nitrogen, helium, argon, or hydrogen is flowed into the process chamber 110 together with the Cl₂ cleaning gas. Moreover, the Cl₂ cleaning gas can effectively clean (i.e., etch) dopant contamination within the process chamber 110 within the deposition temperature range of between around 550° C. and around 680° C. The use of a Cl₂-based clean as described herein, which may be performed at the deposition temperature, eliminates temperature ramp-up/ramp-down times (e.g., as used in conventional, high-temperature HCl-based cleans) which in turn reduces thermal stresses and can extend the lifetime of the susceptor 114. In addition, the in-situ cleans as described with reference to the method 400 advantageously mitigate the accumulation of dopant contamination (e.g., which can occur with each layer deposition performed) within the process chamber 110 and on chamber kit surfaces, as described above.

The method 400 then proceeds to block 408, where a second layer is deposited at a deposition temperature (e.g., temperatures in the range of between around 550° C. and around 680° C.). An embodiment of block 408 may include CVD epitaxial deposition of a second SiP layer having a second phosphorous dopant concentration (e.g., of around 2×10²¹-3×10²¹ cm⁻³), deposition of a second SiGeB layer having a second boron dopant concentration (e.g., of around 2×10²⁰-1×10²¹ cm⁻³), or deposition of another epitaxial layer as known in the art.

The method 400 then proceeds to block 410, where a second clean is performed at the deposition temperature, which may include temperatures in the range of between around 550° C. and around 680° C., as used for the first or second layer depositions at blocks 404, 408. In the embodiments described herein, the second clean is also performed in-situ. In addition, in some embodiments, the in-situ second clean is performed for a time period having a duration which lasts from about 5 seconds to about 20 seconds. By way of example, after deposition of the second layer (block 408), the second clean (block 410) may be performed by flowing the Cl₂ cleaning gas into the process chamber 110, for example while the process chamber 110 remains at the deposition temperature.

The method 400 then proceeds to block 412, where a third layer is deposited at a deposition temperature (e.g., temperatures in the range of between around 550° C. and around 680° C.). An embodiment of block 412 may include CVD epitaxial deposition of a third SiP layer having a third phosphorous dopant concentration (e.g., of around 5×10²⁰-3×10²¹ cm⁻³), deposition of a third SiGeB layer having a third boron dopant concentration (e.g., of around 2×10²⁰-1×10²¹ cm⁻³), or deposition of another epitaxial layer as known in the art.

The method 400 then proceeds to block 414, where a third clean is performed at the deposition temperature, which may include temperatures in the range of between around 550° C. and around 680° C., as used for the first, second, or third layer depositions at blocks 404, 408, 412. In the embodiments described herein, the third clean is also performed in-situ. In addition, in some embodiments, the in-situ third clean is performed for a time period having a duration which lasts from about 5 seconds to about 20 seconds. By way of example, after deposition of the third layer (block 412), the third clean (block 414) may be performed by flowing the Cl₂ cleaning gas into the process chamber 110, for example while the process chamber 110 remains at the deposition temperature.

By performing in-situ cleans after each of the layer depositions (blocks 404, 408, 412), dopant deposition and accumulation within the process chamber 110 (e.g., on the process chamber 100 walls and other chamber surfaces) and on chamber kit surfaces is reduced and/or substantially eliminated. Thus, autodoping (e.g., of the substrate 112 during layer deposition processes) is reduced and/or eliminated, and any subsequent, dedicated cleans (e.g., after the substrate 112 is unloaded) may be substantially easier to perform. In some examples, prior to performing any such dedicated cleans, the method 400 proceeds to block 416 where the substrate 112 is unloaded from the process chamber 110. The method then proceeds to block 418, where a fourth clean is performed at a cleaning temperature. In an embodiment of the block 418, the fourth clean also employs Cl₂ cleaning gas, and the fourth clean may be performed at a cleaning temperature of about 500-600° C. for about 5 seconds to about 20 seconds. In contrast to conventional high-temperature HCl-based cleans, the method 400 substantially mitigates pit and/or other defect formation in the process chamber 110 or chamber kit components. Moreover, the use of Cl₂ cleaning gas (e.g., instead of HCl gas) provides for effective cleaning, even at deposition temperatures (e.g., from about 500-700° C.).

While some examples of methods and systems for cleaning a process chamber 110 (e.g., of the system 100 or the system 500) and chamber kit components have been shown and described, one of skill in the art will recognize that other process steps and/or system components may be included or removed from the methods 300, 400 and/or the systems 100, 500, while remaining within the scope of the present disclosure. For example, the plurality of elevator pins 120 which are moveably coupled to the susceptor 114 may, by way of the lift arms 122, be used to move the susceptor 114 vertically. In some embodiments, moving the susceptor 114 up to a vertical position that is closer to the upper dome 102 provides for enhanced heating of the upper dome 102, for example, by way of convection heating and/or radiation heating due to the closer proximity of the susceptor 114 to the upper dome 102. In other embodiments, moving the susceptor 114 down to a vertical position that is further away from the upper dome 102 provides for exposure of all chamber kit components to the Cl₂ cleaning gas.

The embodiments of the present disclosure offer advantages over existing art, though it is understood that other embodiments may offer different advantages, not all advantages are necessarily discussed herein, and that no particular advantage is required for all embodiments. It will be appreciated that the embodiments of systems and methods for cleaning dopant contamination in a CVD epitaxy system herein provide significant advantages over existing systems and methods. For example, advantages of the embodiments as discussed herein include methods and systems for solving the autodoping issues discussed above. Moreover, present embodiments offer an effective replacement to conventional high-temperature (e.g., greater than about 1200° C.), HCl-based cleans. Specifically, present embodiments include Cl₂-based cleans, which can effectively clean process chamber dopant contamination at temperatures below about 700° C., and down to about 500° C. In contrast to conventional high-temperature HCl-based cleans, embodiments of the Cl₂-based cleans as described herein substantially mitigate pit and/or other defect formation which can occur during aggressive HCl-based cleaning. In various embodiments, the Cl₂-based cleans disclosed herein may be performed at temperatures which are substantially equal to a deposition temperature (e.g., an epitaxial deposition temperature). As a result, present embodiments eliminate temperature ramp-up and ramp-down as performed in conventional HCl-based cleans, thus saving time, reducing thermal cycles, and extending susceptor lifetime. In addition, embodiments of the present disclosure present in-situ cleans that may be integrated within/between epitaxial growth process steps, mitigating dopant contamination build-up occurring during the epitaxial growth process and simplifying any subsequent, dedicated cleaning process performed after a substrate is unloaded from the CVD epitaxy system. Moreover, present embodiments include systems (such as the system 500 of FIG. 5) with dedicated lamps that provide for enhanced heating of chamber kit components. Yet another advantage of the present embodiment includes systems having a moveable susceptor, for example, to improve heating of the upper dome and exposure of one or more chamber kit components to cleaning reactants.

Thus, one of the embodiments of the present disclosure described a system for cleaning dopant contamination. In various embodiments, the system includes a susceptor disposed within a process chamber, at least one chamber kit component disposed within the process chamber, a first plurality of lamps configured to heat the susceptor, a second plurality of lamps configured to heat the at least one chamber kit component, and a gas supply configured to provide a chlorine cleaning gas to the process chamber. The system is configured to deposit a doped semiconductor layer on a substrate loaded on the susceptor at a deposition temperature. The system is further configured to perform an in-situ clean of the process chamber, and including the at least one chamber kit component, at the deposition temperature.

In another of the embodiments, discussed is a method for cleaning dopant contamination. In some embodiments, an epitaxial layer is deposited over a substrate loaded onto a susceptor in a process chamber at a deposition temperature. An in-situ clean of the process chamber and at least one process kit component is performed at the deposition temperature. The substrate is unloaded from the process chamber, and a dedicated clean of the process chamber and the at least one process kit component is performed at a clean temperature. In some embodiments, the clean temperature is substantially equal to the deposition temperature.

In yet another of the embodiments, discussed is a method for semiconductor device fabrication. In some embodiments, a plurality of layers is deposited over a substrate in a process chamber at a first temperature. In various embodiments, prior to unloading the substrate from the process chamber, a cleaning gas is flowed into the process chamber, and at least one in-situ clean of the process chamber and at least one process kit component is performed at the first temperature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system for cleaning dopant contamination, comprising:
a susceptor disposed within a process chamber;
at least one chamber kit component disposed within the process chamber;
a first plurality of lamps configured to heat the susceptor; and
a second plurality of lamps configured to heat the at least one chamber kit component;
wherein the system is configured to deposit a doped semiconductor layer on a substrate loaded on the susceptor at a deposition temperature; and
wherein the system is configured to perform an in-situ clean of the process chamber, and including the at least one chamber kit component, at the deposition temperature.

2. The system of claim 1, further comprising:
an upper dome at least partially enclosing the process chamber;
a plurality of elevator pins moveably coupled to the susceptor; and
a plurality of lift arms configured to engage the elevator pins and vertically displace the susceptor from a first position to a second position, wherein a distance between the susceptor and the upper dome is smaller when the susceptor is in the second position.

3. The system of claim 2, wherein the system is configured to perform the in-situ clean while the susceptor is in the second position in order to increase an upper dome temperature.

4. The system of claim 2, wherein the system is configured to perform the in-situ clean while the susceptor is in the first position in order to expose the at least one chamber kit component to a cleaning gas.

5. The system of claim 1, further comprising a gas supply fluidly coupled to the process chamber, wherein the gas supply is configured to provide to the process chamber at least one of a carrier gas, a precursor gas, a dopant gas, and a cleaning gas.

6. The system of claim 5, wherein the gas supply is configured to provide to the process chamber a chlorine cleaning gas and a carrier gas.

7. The system of claim 1, wherein the at least one chamber kit component includes one selected from the group comprising: the susceptor; an upper dome; a lower dome; an upper base ring; a lower base ring; an upper clamp ring; a lower clamp ring; an upper liner; a lower liner; and a pre-heat ring.

8. The system of claim 1, further comprising at least one pyrometer configured to measure a system temperature, wherein the system is configured to control a power setting of at least one lamp of the first and second plurality of lamps based on the system temperature measurement of the at least one pyrometer.

9. A method of cleaning dopant contamination, comprising:
depositing an epitaxial layer over a substrate loaded onto a susceptor in a process chamber at a deposition temperature;
performing an in-situ clean of the process chamber and at least one process kit component at the deposition temperature;
unloading the substrate from the process chamber; and
after the unloading the substrate from the process chamber, performing a dedicated clean of the process chamber and the at least one process kit component at a clean temperature.

10. The method of claim 9, wherein the deposition temperature is between about 500° C. and about 700° C.

11. The method of claim 9, wherein the in-situ clean is performed for a duration of from about 5 seconds to about 20 seconds.

12. The method of claim 9, wherein the performing the in-situ clean further comprises flowing a chlorine gas into the process chamber.

13. The method of claim 12, wherein the performing the in-situ clean further comprises flowing at least one of a helium gas and a nitrogen gas.

14. The method of claim 9, further comprising:
moving, by way of a lift arm engaged with an elevator pin movably coupled to the susceptor, the susceptor from a first position to a second position;
wherein a distance between the susceptor and an upper dome is smaller when the susceptor is in the second position; and
wherein, while the susceptor is in the second position, the upper dome is heated by at least one of convection and radiation heating due to the proximity of the susceptor to the upper dome.

15. The method of claim 14, further comprising:
moving, by way of the lift arm engaged with the elevator pin, the susceptor from the second position to the first position, wherein the at least one process kit component is exposed as a result of the moving the susceptor to the first position.

16. A method of semiconductor device fabrication, comprising:
depositing a plurality of layers over a substrate in a process chamber at a first temperature;
prior to unloading the substrate from the process chamber, flowing a cleaning gas into the process chamber; and
performing, while the substrate remains in the process chamber, at least one clean of the process chamber and at least one process kit component at the first temperature.

17. The method of claim 16, further comprising:
unloading the substrate from the process chamber; and
performing a dedicated clean of the process chamber and the at least one process kit component at a second temperature.

18. The method of claim 17, wherein the first temperature is about equal to the second temperature.

19. The method of claim 16, further comprising:
after depositing each layer of the plurality of layers, performing a clean of the process chamber and the at least one process kit component at the first temperature while the substrate remains in the process chamber.

20. The method of claim 16, wherein the cleaning gas includes a chlorine gas.
